(19) United States
(12) Patent Application Publication
(10) Pub. No.: US 2026/0354052 A1
(43) Pub. Date: Nov. 5, 2026

(54) METHOD FOR FORMING A LAYER OF SILICON CARBIDE

(71) Applicant: SOITEC, BERNIN (FR)

(72) Inventors: Djamel Belhachemi, BERNIN (FR); Didier Landru, BERNIN (FR); Oleg Kononchuk, BERNIN (FR)

(21) Appl. No.: 19/124,594

(22) PCT Filed: Oct. 25, 2023
(86) PCT No.: PCT/FR2023/051674

§ 371 Date: Apr. 25, 2025

(30) Foreign Application Priority Data
Oct. 27, 2022 (FR) 2211212

(51) Int. Cl. H10P 14/20; H10P 30/20; H10P 50/26; H10P 90/00

(52) U.S. Cl. CPC H10P 14/3408; H10P 14/2905; H10P 14/3602; H10P 30/202; H10P 50/267; H10P 90/1904; H10P 90/1916

(57) ABSTRACT

A method for forming a respective layer of silicon carbide on a plurality of silicon substrates consecutively comprises:—placing a plurality of vertically stacked silicon base substrates in a furnace, a vertical gap being provided between two adjacent silicon base substrates; —etting a stream of a carbon-containing gas into the furnace;—raising the temperature to a temperature at which a layer of silicon carbide is formed in order to simultaneously form, via reaction of the carbon-containing gas with the silicon, a layer of silicon carbide on the surface of each silicon base substrate and a layer of carbon on each layer of silicon carbide;—removing each layer of carbon.

### CROSS-REFERENCE TO RELATED APPLICATIONS

This application is a national phase entry under 35 U.S.C. § 371 of International Patent Application PCT/FR2023/051674, filed Oct. 25, 2023, designating the United States of America and published as International Patent Publication WO 2024/089359 A 1 on May 2, 2024, which claims the benefit under Article 8 of the Patent Cooperation Treaty of French Patent Application Serial No. FR 2211212, filed Oct. 27, 2022.

### TECHNICAL FIELD

The present disclosure relates to a process for fabricating a semiconductor-on-insulator or piezoelectric-on-insulator substrate for radiofrequency applications.

### BACKGROUND

Radiofrequency (RF) devices, which process signals having a frequency of between about 10 MHz and 300 GHz, are notably applicable in the field of telecommunications.

Such devices can be formed from semiconductor-on-insulator or piezoelectric-on-insulator substrates, comprising successively a base substrate, an electric-charge-trapping layer (referred to as a trap-rich layer), a dielectric layer positioned on the trap-rich layer and a semiconductor or piezoelectric active layer positioned on the dielectric layer. Active and/or passive components are formed in and/or on the active layer.

The trap-rich layer prevents the appearance of a conductive plane under the electrically insulating layer and the drop in the resistivity of the base substrate. Moreover, such a layer eliminates charge carriers in the substrate that may generate harmonics liable to interfere with the signals propagating in the radiofrequency device and to degrade their quality.

The trap-rich layer may be made of silicon carbide (SiC). The formation of such a layer is typically carried out by epitaxy on the base substrate, in order to obtain the crystalline quality necessary for effective harmonic suppression in the RF component. This step is followed by chemical-mechanical polishing (CMP) in order to obtain a uniform thickness and a sufficiently smooth surface of the silicon carbide layer.

The epitaxial deposition of a sufficiently thick layer of SiC is slow and consequently expensive. In addition, an epitaxy chamber receives a single substrate or a reduced number of substrates.

Moreover, during an epitaxy process, the base substrate is heated via its back face. This technique does not allow precise control of the temperature of the front face. This may cause the deposited silicon carbide layer to disappear in the event of an excessively high temperature of the front face.

### BRIEF SUMMARY

One objective of the present disclosure is to design a process for fabricating an SiC layer on a silicon substrate, in particular for forming a substrate for radiofrequency applications, which is faster and less expensive than known processes.

To this end, the disclosure proposes a process for forming a respective silicon carbide layer on a plurality of silicon substrates, the process successively comprising:
placing a plurality of vertically superimposed silicon base substrates in a furnace, a vertical space being made between two adjacent base substrates,
introducing a flow of a carbon-containing gas into the furnace,
increasing to a temperature for forming a silicon carbide layer in order to form simultaneously, by a reaction of the carbon-containing gas with the silicon, a silicon carbide layer on the surface of each base substrate and a carbon layer on each silicon carbide layer, and
removing each carbon layer.

Preferably, the carbon-containing gas is propane or acetylene.

Advantageously, the carbon-containing gas is mixed with argon or a mixture of argon and hydrogen.

Advantageously, the temperature for forming the silicon carbide layer is between 750 °C and 1100 °C.

Typically, the temperature for removing the carbon layer is between 600 °C and 950 °C.

Preferably, the silicon substrate has an electrical resistivity of greater than 500 ohm. cm.

Advantageously, the thickness of the silicon carbide layer is between 2 and 5 nm.

Advantageously, the process further comprises, prior to the introduction of the flow of carbon-containing gas:
heating the furnace to a temperature for decomposition of a native silicon oxide,
removing a native silicon oxide layer from the base substrate by thermal decomposition of the oxide, and
cooling the furnace to a temperature for introduction of the propane flow.

Preferably, the formation of the silicon carbide layer and the removal of the carbon layer are carried out in the same furnace.

In certain embodiments, the removal of the carbon layer is carried out by introducing an oxygen flow into the furnace and reacting the carbon layer with the oxygen flow.

In other embodiments, the removal of the carbon layer is carried out by an oxygen plasma etching process.

The disclosure also relates to a process for fabricating a semiconductor-on-insulator or piezoelectric-on-insulator substrate for radiofrequency applications, comprising the following steps:
forming a silicon carbide layer on a silicon substrate as described above in order to form a carrier substrate,
forming a weakened zone by implantation of atomic species in a donor substrate made of a semiconductor or piezoelectric material,
bonding the donor substrate to the front face of the carrier substrate, a dielectric layer being arranged between the silicon carbide layer and the donor substrate, and
detaching the donor substrate along the weakened zone so as to transfer a layer of the semiconductor or piezoelectric material to the carrier substrate.

### BRIEF DESCRIPTION OF THE DRAWINGS

Other features and advantages of the disclosure will become apparent from the detailed description that follows, with reference to the appended drawings, in which:

FIGS. 1A and 1B are schematic views of a base substrate before a process according to the disclosure.

FIG. 2 is a schematic view of a base substrate comprising a silicon carbide layer and a carbon layer.

FIG. 3 is a schematic view of a base substrate comprising a silicon carbide trap-rich layer.

FIG. 4 shows the thermal profile used for a process according to the disclosure.

FIGS. 5A to 5D illustrate the steps for fabricating a semiconductor-on-insulator or piezoelectric-on-insulator substrate.

FIG. 6 illustrates an annealing furnace suitable for forming a silicon carbide layer on the base substrate and a carbon layer on the silicon carbide layer according to a preferred embodiment of the disclosure.

### DETAILED DESCRIPTION

### Formation of the Silicon Carbide Layer

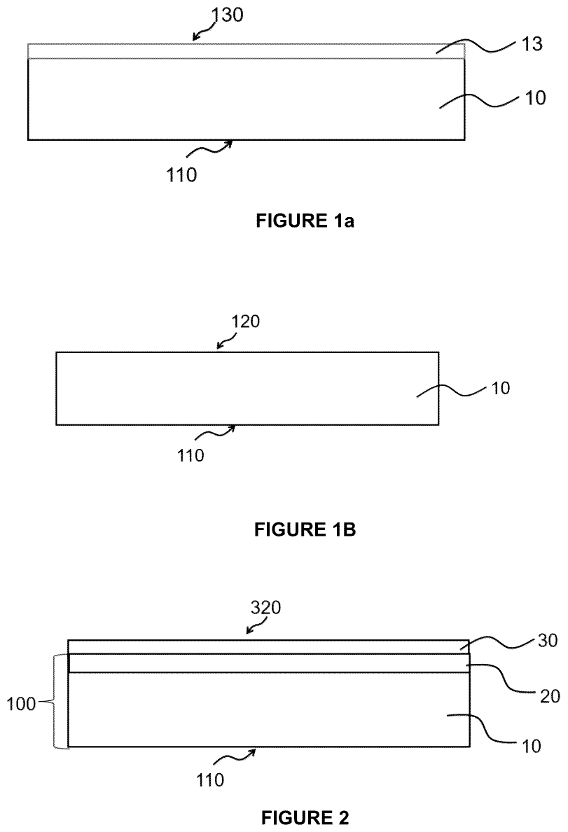

FIG. 1A illustrates a silicon base substrate 10 intended for fabricating a semiconductor-on-insulator or piezoelectric-on-insulator substrate. The electrical resistivity of such a base substrate is advantageously greater than 500 ohm. cm. The base substrate has a back face 110 and a front face 130. Typically, in its starting state, the base substrate has a native silicon oxide layer 13 on its surface.

In order to prepare the front face for the subsequent steps, the native oxide layer is first removed. This step is typically carried out in a furnace at a temperature of between 950 °C and 1150 °C, preferably close to 1100 °C, under an inert atmosphere. At the end of this step, with reference to FIG. 1B, the substrate has a front face 120 made of silicon.

A silicon carbide layer 20 is then formed on the front face 120 of the base substrate. The silicon carbide layer is formed in a furnace, which will be described later. Advantageously, the removal of the native oxide layer is carried out in the same furnace in order to avoid transfer steps leading to a loss of time and energy for the subsequent cooling and heating, and a need for additional labor.

The silicon carbide layer is formed in the gas phase, i.e., carbon is present in the furnace in the form of a carbon-containing gas, for example, propane (C₃H₈) or acetylene (C₂H₄) gas. The carbon-containing gas is mixed with a carrier gas, for example, argon or a mixture of argon and hydrogen.

The substrate is heated in the furnace to a temperature for forming the silicon carbide layer. The carbon gas phase is converted to silicon carbide by reaction with the silicon on the surface of the substrate. The reaction is self-limited, i.e., when all the surface silicon of the front face of the base substrate has been consumed, the carbonizing reaction stops. No additional silicon source is provided. The final thickness of the silicon carbide layer 20 is between 2 and 5 nm. Simultaneously, with reference to FIG. 2, a carbon layer 30 is formed on the silicon carbide layer 20. At the end of this step, the substrate has a front face 320 made of carbon.

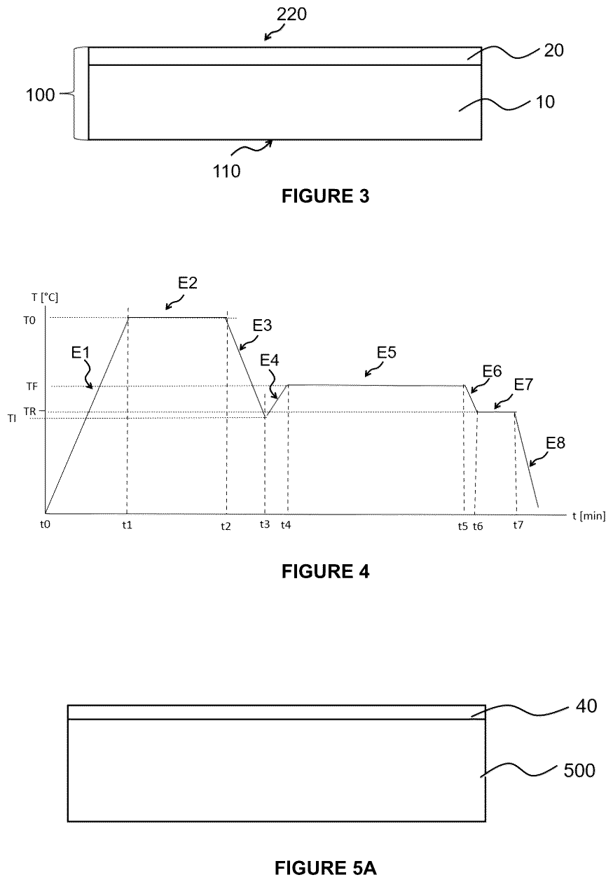

Next, with reference to FIG. 3, the carbon layer is removed. Advantageously, this removal is carried out by supplying oxygen to the front face of the base substrate.

In certain embodiments, the removal of the carbon layer is carried out by introducing an oxygen flow into the furnace and reacting the carbon layer with the oxygen flow. In this case, the removal of the oxygen layer is advantageously carried out in the same furnace as the deposition of the silicon carbide layer. This treatment is therefore carried out in situ and does not require any step of cooling in or transferring to another chamber. Removal by an oxygen flow in the same furnace makes it possible to obtain a roughness of the front face 220 that is low enough for the subsequent steps to form a semiconductor-on-insulator or piezoelectric-on-insulator substrate for radiofrequency applications.

In other embodiments, the removal of the carbon layer is carried out by an oxygen plasma etching process. This removal is effective; however, it requires a step of transferring the substrate to another chamber. In addition, the plasma treatment can degrade the roughness of the front face 220 of the base substrate, which involves subsequent treatment to improve the surface quality.

FIG. 4 illustrates an example of a temperature profile for a process for forming a silicon carbide layer on a silicon substrate in an annealing furnace as a function of the elapsed time. In this case, all the steps from the removal of the native oxide layer to the removal of the carbon layer are carried out in the same furnace.

Eight steps of the process can be distinguished:

The first step E1 begins at a time t0. The base substrate comprising a native oxide layer is at a temperature for introduction into the furnace, which is typically below or equal to 500 °C. The substrate is introduced into the furnace. The base substrate begins to be heated to a temperature To for removal of the native oxide layer. This heating may, in an illustrative and non-limiting manner, comprise temperature increases of 5 °C/min up to 900 °C, then of 2 °C/min up to 1000 °C, and of 1 °C/min up to 1100 °C. At time t1, the temperature To for removal of the native oxide is reached.

The temperature To for removing the native oxide is between 1000 °C and 1200°C, preferably close to 1100 °C. This temperature is maintained during step E2, which typically lasts about 20 minutes until t2. The duration of this step E2 may vary depending on the thickness of the native oxide layer.

Cooling is then carried out during step E3 down to a temperature T₁ for injecting carbon-containing gas into the furnace at time t3. For example, the cooling can be carried out at a rate of 5 °C/min and the gas injection temperature T₁ is about 750 °C.

After the injection of the carbon-containing gas and the carrier gas, the substrate is heated in step E4 to a temperature T_{F} for forming a silicon carbide layer. The temperature T_{F} for forming the silicon carbide layer 20 is advantageously between 750 °C and 1100 °C. Nucleation of the silicon carbide on the surface of the substrate begins during the increase in temperature between t3 and t4 during step E4 and stops when the silicon on the surface of the base substrate has been converted to silicon carbide. The SiC formation reaction stops during the increase in temperature, when all the silicon has been consumed. Next, a carbon layer is formed, which is related to the high-temperature decomposition of the carbon-containing gas. The temperature T_{F} is maintained during step E5 during which the carbon-containing gas is evacuated from the furnace under a flow of carrier gas over about 10 minutes. Subsequently, still at temperature T_{F}, the silicon carbide layer is annealed, for example, for a period of 2 hours, until t5.

Cooling E6 is then carried out down to a temperature T_{R} for removing the carbon layer. The temperature T_{R} is reached at time t6 and is between 600 °C and 950 °C. In an illustrative and non-limiting manner, this temperature may be in the region of 800 °C. In the removal step E7, the removal temperature T_{R} is maintained and oxygen O₂ is injected into the furnace. For example, for an injection at 2 to 20 slm, the duration of the removal of the carbon layer is about 5 minutes, until t7. Next, in a final step E8, the temperature is lowered in order to remove the substrate from the furnace.

Fabrication of a semiconductor-on-insulator or piezoelectric-on-insulator substrate:

The base substrate comprising the trap-rich layer made of silicon carbide can now be used for the fabrication of a semiconductor-on-insulator or piezoelectric-on-insulator substrate for radiofrequency applications.

The steps will now be described for producing such a substrate comprising a base substrate having a trap-rich layer produced according to a process as described above, a semiconductor layer on its surface, and an electrically insulating layer, which is arranged at the interface between the trap-rich layer and the semiconductor surface layer.

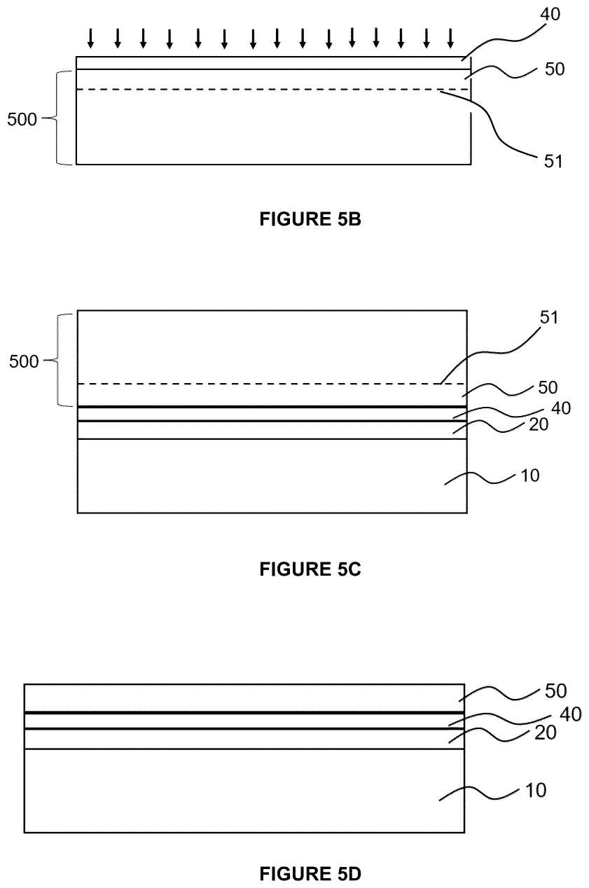

With reference to FIG. 5A, the first step is to provide a semiconductor or piezoelectric donor substrate 500 from which a semiconductor or piezoelectric layer will be transferred onto the base substrate and the trap-rich layer. An electrically insulating layer 40 is formed on the surface of the donor substrate 500.

With reference to FIG. 5B, as shown schematically by the arrows, an ion species implantation is performed using, for example, hydrogen and/or helium ions, through the electrically insulating layer 40, so as to form a weakened zone 51 in the donor substrate 500. The weakened zone 51 defines the semiconductor or piezoelectric layer 50 to be transferred.

With reference to FIG. 5C, the donor substrate 500 thus implanted is bonded to the trap-rich layer 20 on the base substrate 10 by way of the electrically insulating layer 40. The latter then becomes a buried oxide layer 40.

Alternatively, the electrically insulating layer (40) may be formed on the trap-rich layer on the base substrate, and the donor substrate 500 comprising the weakened zone 51 can be bonded to the base substrate 10 comprising the trap-rich silicon carbide layer 20 and the electrically insulating layer 40.

With reference to FIG. 5D, the donor substrate 500 is detached along the weakened zone 51, resulting in the semiconductor or piezoelectric layer 50 being transferred to the carrier substrate 100. The electrically insulating layer 40 is arranged between the trap-rich layer 20 and the semiconductor or piezoelectric layer 50. A finishing treatment may subsequently be applied to the transferred layer 50, so as to heal defects related to the implantation and to smooth the free surface of the layer 50. The semiconductor-on-insulator or piezoelectric-on-insulator structure is now complete and can be used for the fabrication of components for radiofrequency applications.

Furnace overview:

In order to make a process for treating a plurality of substrates fast and efficient, an annealing furnace that can treat a maximum number of substrates simultaneously under identical conditions is preferably used. Such a furnace is conventionally referred to as a batch anneal furnace in the microelectronics field.

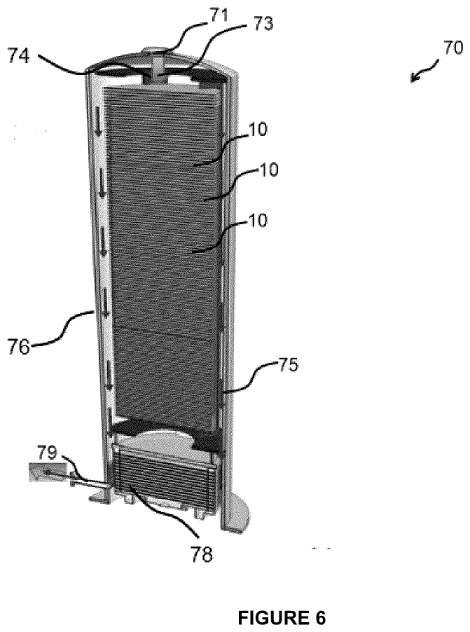

FIG. 6 illustrates a furnace 70 suitable for receiving an amount of between 120 and 150 substrates in an annealing chamber. The substrates 10 are positioned horizontally in the furnace 70 and are superposed vertically in order to treat as many substrates as possible in the same flow 73 of hot gas. A clearance is maintained between each substrate 10 and the adjacent substrates 10 to optimize the gas flow and facilitate the formation of the silicon carbide layer.

Such a furnace 70 uses a “top flow” configuration, i.e., a stream of gas is fed into the furnace from the top 71 and, after passing through the furnace, is discharged through an outlet 79 at the bottom of the furnace. Typically, one gas flow transports the carrier gas, and a second gas flow supplies a carbon-containing gas such as propane or acetylene.

All the elements of the annealing chamber inside the furnace, i.e., the inner walls 75, the substrate holders for holding the substrates in a horizontal and vertically superposed position, and the gas included in the annealing chamber are at the same temperature during use of the furnace, with the exception of the outer elements such as the outer wall 76 and the ends of the gas inlet pipes. The term “same temperature” means that the difference in temperature between the top end 74 of the furnace and the bottom end 78 of the furnace is minimal, typically a few degrees Celsius, for example, less than 3 degrees for a temperature in the furnace of between 800 °C and 1200 °C.

The substrates are heated mainly by conduction from the walls of the furnace. The gas streams are injected at the same temperature as the temperature inside the furnace.

Such a furnace makes it possible to simultaneously treat a large number of substrates by virtue of the vertically superposed arrangement. Moreover, such a furnace makes it possible to carry out the step of removing the native oxide layer, the step of depositing the silicon carbide layer and the step of removing the carbon layer in the same chamber, which avoids the risk of contamination during a transfer between two different chambers. Steps of transferring between different chambers suitable for the respective steps are avoided, thus avoiding cooling between the steps, the need for labor for the transfer and thus a loss of time and efficiency.

1. A method of forming a respective silicon carbide layer on a plurality of silicon substrates, the method successively comprising:
placing a plurality of vertically superposed silicon base substrates in a furnace, a vertical space being made between two adjacent silicon base substrates, substrates;
introducing a flow of a carbon-containing gas into the furnace;
increasing to a temperature for forming a silicon carbide layer in order to form simultaneously, by a reaction of the carbon-containing gas with the plurality of vertically superposed silicon base substrates, a silicon carbide layer on the a surface of each silicon base substrate and a carbon layer on each silicon carbide layer; and
removing each carbon layer.

2. The method of claim 1, wherein the carbon-containing gas is propane or acetylene.

3. The method of claim 2, wherein the carbon-containing gas is mixed with argon or a mixture of argon and hydrogen.

4. The method of claim 3, wherein the temperature for forming the silicon carbide layer is between 750 °C and 1100 °C.

5. The method of claim 4, wherein the temperature for removal of the carbon layer is between 600 °C and 950 °C.

6. The method of claim 5, wherein the silicon substrate of each of the plurality of vertically superposed silicon substrates has an electrical resistivity of greater than 500 ohm.cm.

7. The method of claim 6, wherein a thickness of the silicon carbide layer is between 2 and 5 nm.

8. The method of claim 7, further comprising, prior to introducing the flow of the carbon-containing gas:
heating the furnace to a temperature for decomposition of a native silicon oxide;
removing a native silicon oxide layer from the base substrate by thermal decomposition of the native silicon oxide; and
cooling the furnace to a temperature for introduction of the carbon-containing gas.

9. The method of claim 8, wherein formation of the silicon carbide layer and removal of the carbon layer are carried out in the same furnace.

10. The method of claim 9, wherein the removal of the carbon layer is carried out by introducing an oxygen flow into the furnace and reacting the carbon layer with the oxygen flow.

11. The method of claim 9, wherein the removing of each carbon layer is carried out by an oxygen plasma etching process.

12. A method of fabricating a semiconductor-on-insulator or piezoelectric-on-insulator substrate for radiofrequency applications, comprising the following steps:
forming a silicon carbide layer on a silicon substrate according to any one of the preceding claims in order to form a carrier substrate;
forming a weakened zone by implantation of atomic species in a donor substrate made of a semiconductor or piezoelectric material;
bonding the donor substrate to the front face of the carrier substrate, a dielectric layer being arranged between the silicon carbide layer and the donor substrate; and
detaching the donor substrate along the weakened zone so as to transfer a layer of the semiconductor or piezoelectric material to the carrier substrate.

13. The method of claim 1, wherein the carbon-containing gas is mixed with argon or a mixture of argon and hydrogen.

14. The method of claim 1, wherein the temperature for forming the silicon carbide layer is between 750 °C and 1100 °C.

15. The method of claim 1, wherein the temperature for removal of the carbon layer is between 600 °C and 950 °C.

16. The method of claim 1, wherein the plurality of vertically superposed silicon base substrates has an electrical resistivity of greater than 500 ohm.cm.

17. The method of claim 1, wherein a thickness of the silicon carbide layer is between 2 and 5 nm.

18. The method of claim 1, further comprising, prior to introducing the flow of the carbon-containing gas:
heating the furnace to a temperature for decomposition of a native silicon oxide;
removing a native silicon oxide layer from the base substrate by thermal decomposition of the native silicon oxide; and
cooling the furnace to a temperature for introduction of the carbon-containing gas.

19. The method of claim 1, wherein formation of the silicon carbide layer and removal of the carbon layer are carried out in the same furnace.

20. The method of claim 1, wherein the removing of each carbon layer is carried out by an oxygen plasma etching process.
